(19) United States
(12) Patent Application Publication
(10) Pub. No.: US 2025/0008646 A1
(43) Pub. Date: Jan. 2, 2025

(54) POWER SUPPLY BOARDS FOR WIRELESS COMMUNICATIONS DEVICES

(71) Applicant: PLUME DESIGN, INC., Palo Alto, CA (US)

(72) Inventor: Chiu-Wen CHEN, Taichung City (TW)

(21) Appl. No.: 18/757,701

(22) Filed: Jun. 28, 2024

Related U.S. Application Data
(60) Provisional application No. 63/510,898, filed on Jun. 29, 2023.

(51) Int. Cl. H05K 1/02; H05K 1/11

(52) U.S. Cl. CPC H05K 1/0298; H05K 1/0201; H05K 1/0231; H05K 1/115; H05K 2201/068; H05K 2201/10015; H05K 2201/10098; H05K 2201/10181; H05K 2201/10196

(57) ABSTRACT

Power supply boards may include a printed circuit board (PCB) substrate including power supply circuitry, an input electrolytic capacitor mounted to the PCB substrate and operably coupled to the power supply circuitry, and a Y-capacitor that may be surface-mounted to the PCB substrate on an opposing side of the PCB substrate from the input electrolytic capacitor. The Y-capacitor may be operably coupled to the power supply circuitry.

### CROSS-REFERENCE TO RELATED APPLICATIONS

This application claims the benefit of U.S. Provisional Patent Application Ser. No. 63/510,898, titled “POWER SUPPLY BOARDS FOR WIRELESS COMMUNICATIONS DEVICES,” filed on 29 Jun. 2023, the entire disclosure of which is incorporated herein by this reference.

### BRIEF DESCRIPTION OF DRAWINGS

The accompanying drawings illustrate a number of example embodiments and are a part of the specification. Together with the following description, these drawings demonstrate and explain various principles of the present disclosure.

FIG. 1 is a plan view of a power supply board for a wireless communications device, according to at least one embodiment of the present disclosure.

FIGS. 2A and 2B are views of a transformer bobbin for use with a power supply board, and FIGS. 2C and 2D are views of a corresponding transformer core, according to at least one embodiment of the present disclosure. The view of FIG. 2D is taken from line 2D-2D of FIG. 2C.

FIG. 3 is a schematic circuit diagram of a power supply board for a wireless communications device, according to at least one embodiment of the present disclosure.

FIGS. 4-14 illustrate a printed circuit layout of respective layers of a power supply board for a wireless communications device, according to at least one embodiment of the present disclosure.

FIG. 15 is a flow diagram illustrating a method of forming a power supply board, according to at least one embodiment of the present disclosure.

Throughout the drawings, identical reference characters and descriptions indicate similar, but not necessarily identical, elements. While the example embodiments described herein are susceptible to various modifications and alternative forms, specific embodiments have been shown by way of example in the drawings and will be described in detail herein. However, the example embodiments described herein are not intended to be limited to the particular forms disclosed. Rather, the present disclosure covers all modifications, equivalents, and alternatives falling within this disclosure.

### DETAILED DESCRIPTION OF EXAMPLE EMBODIMENTS

Power supply boards may be used to provide power to electronic devices (e.g., wireless communications devices, such as wireless signal extenders). The power supply boards may convert an input power (e.g., alternating current power) into an output power (e.g., direct current power) that can be used by the electronic devices.

The present disclosure is generally directed to power supply boards for wireless communications devices, such as wireless signal extenders. The power supply boards of the present disclosure may include certain components and arrangements of components, as described below and as shown in the accompanying drawings by way of example.

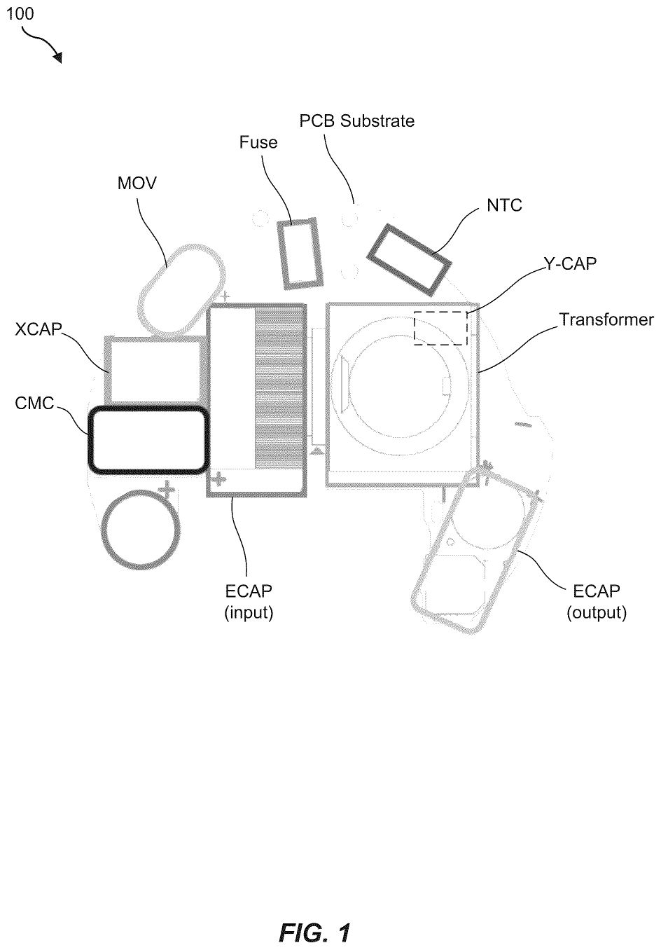

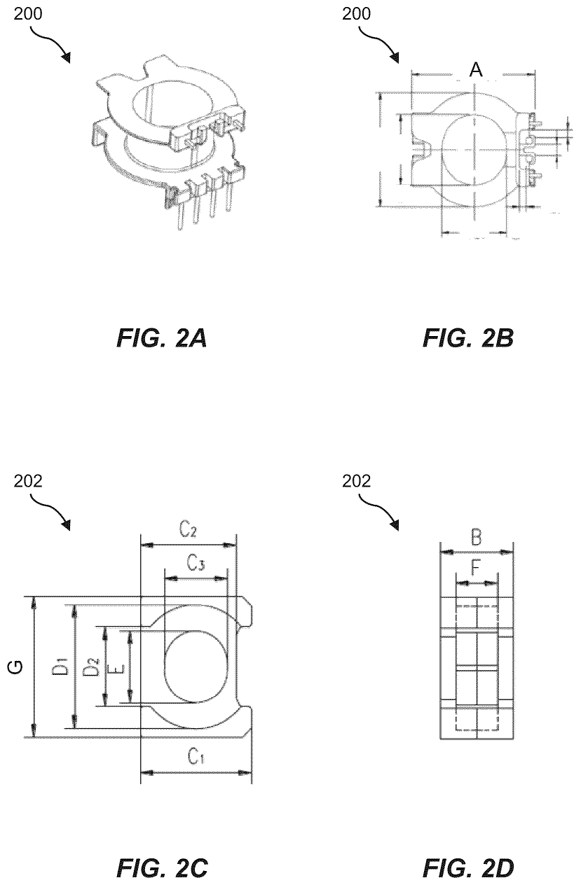

FIG. 1 is a plan view of a power supply board 100 for a wireless communications device, according to at least one embodiment of the present disclosure. The power supply board 100 may include a printed circuit board (“PCB”) substrate 102 for supporting and electrically coupling the various components of the power supply board 100 in a power supply circuit. The following components may be operably mounted to the PCB substrate 102. A negative temperature coefficient thermistor 104 (“NTC”) may be configured for limiting inrush current to protect the power supply circuit, such as when the wireless communications device is turned on. A metal oxide varistor 106 (“MOV”) may be configured for protecting the power supply circuit from high-voltage spikes. An input electrolytic capacitor 108 (“input ECAP”) and an output electrolytic capacitor 110 (“output ECAP”) may be employed for decoupling and/or noise filtering. An X-capacitor 112 (“XCAP”) may be configured for reducing electromagnetic interference and/or radio frequency interference in the power supply circuit. A common-mode choke 114 (“CMC”) may be configured for filtering high-frequency interferences. A transformer 116 may be configured to step up and/or step down voltage in the power supply circuit. The transformer 116 may include a bobbin and a ferrite core, which may have a configuration for reducing a size thereof as described below with reference to FIGS. 2A-2D. A fuse 118 may be configured to protect the power supply circuit from overcurrent. A surface-mounted Y-capacitor 120 (“Y-CAP”) may also be used in the power supply circuit.

In some examples, the Y-CAP 120 may be positioned on a back side (e.g., an opposite side compared to the view of FIG. 1) of the PCB substrate 102 relative to the other components shown in FIG. 1 and described above. Additionally, other components for proper functioning of the power supply board 100 may be present on or in the PCB substrate 102.

By way of example, these components may be arranged on the PCB substrate 102 as illustrated in FIG. 1 and may be interconnected (e.g., via the PCB substrate 102 and/or via connectors) and operably coupled to each other for functioning of the power supply circuit.

In some examples, the input ECAP 108 may include a single large electrolytic capacitor that is coupled to the PCB substrate 102 (e.g., instead of two or more smaller input electrolytic capacitors). The input ECAP 108 may be mounted to the PCB substrate 102 in a bent configuration (e.g., in a 90-degree bent configuration) such that a body of the input ECAP lies along a surface of the PCB substrate 102. This bent configuration of the input ECAP 108 may reduce a height of the power supply board 100 compared to an upright input ECAP 108 and may enable the power supply board 100 to be used in a wireless communication device that is more compact (e.g., having a smaller height) than would otherwise be possible with a power supply board with an upright input ECAP 108.

In some examples, the use of a surface-mounted Y-CAP 120 may also provide a more compact power supply board 100 compared to other configurations, such as when a dip-style capacitor is used. Mounting the surface-mounted Y-CAP 120 to a back side of the PCB substrate 102 may also reduce an amount of lateral space on the PCB substrate 102 required to mount the components of the power supply board 100.

In some examples, the transformer 116 may include a bobbin with improved space utilization. For example, a transformer bobbin according to some embodiments of the present disclosure may be configured as shown in FIGS. 2A-2D and as explained below.

FIGS. 2A and 2B are views of a transformer bobbin 200 for use with a power supply board (e.g., the power supply board 100 of FIG. 1), and FIGS. 2C and 2D are various views of a corresponding transformer core 202, according to at least one embodiment of the present disclosure. The view of FIG. 2D is taken from line 2D-2D of FIG. 2C.

The transformer bobbin 200 may have a configuration as shown in FIGS. 2A-2B. In some examples, pins of the transformer bobbin 200 (FIG. 2A) may be positioned on an upper level and a lower level of the transformer bobbin 200 to reduce an overall transformer size. For example, the transformer bobbin 200 may include a lower flange 204, lower pins 206 extending downward from the lower flange 204, a central cylinder 208 extending upward from the lower flange 204, an upper flange 210 on an opposing side of the central cylinder 208 from the lower flange 204, and upper pins 212 extending (e.g., outward) from the upper flange 210. The central cylinder 208 may be configured for coiling a wire around the central cylinder 208.

Referring to FIGS. 2C and 2D, the transformer core 202 may be shaped and sized to be complementary to the transformer bobbin 200, such as to fit at least partially around the transformer bobbin 200. The transformer core 202 may at least partially be formed of a ferrite material. The transformer core 202 may include a peripheral recess 214 to accommodate the lower pins 206 of the transformer bobbin 200. In other words, when the transformer bobbin 200 and the transformer core 202 are coupled to each other, the lower pins 206 of the transformer bobbin 200 may pass through the peripheral recess 214.

The presence of the upper pins 212 of the transformer bobbin 200 in place of one or more lower pins 206 may enable the lower pins 206 to be narrower than a set of lower pins 206 that otherwise has an increased quantity of lower pins 206. The narrower size of lower pins 206 may enable the lower pins 206 to fit inside the peripheral recess 214 of the transformer core 202, as noted above. Thus, a resulting transformer size may be more compact.

For example, a ratio of a maximum bobbin width A (FIG. 2B) of the transformer bobbin 200 to an internal core width C₂ (FIG. 2C) of the transformer core 202 may be less than 150%, such as 145% or lower, 140% or lower, 135% or lower, or 130% or lower.

By way of example and not limitation, values for some of the dimensions shown in FIGS. 2B and 2C may be as follows: the maximum bobbin width A may be about 21.1+/−0.3 mm, an outer core width C₁ may be about 19+/−0.5 mm, the internal core width C₂ may be about 16.4+/−0.5 mm, and a core length G may be about 23.2+/−0.5 mm.

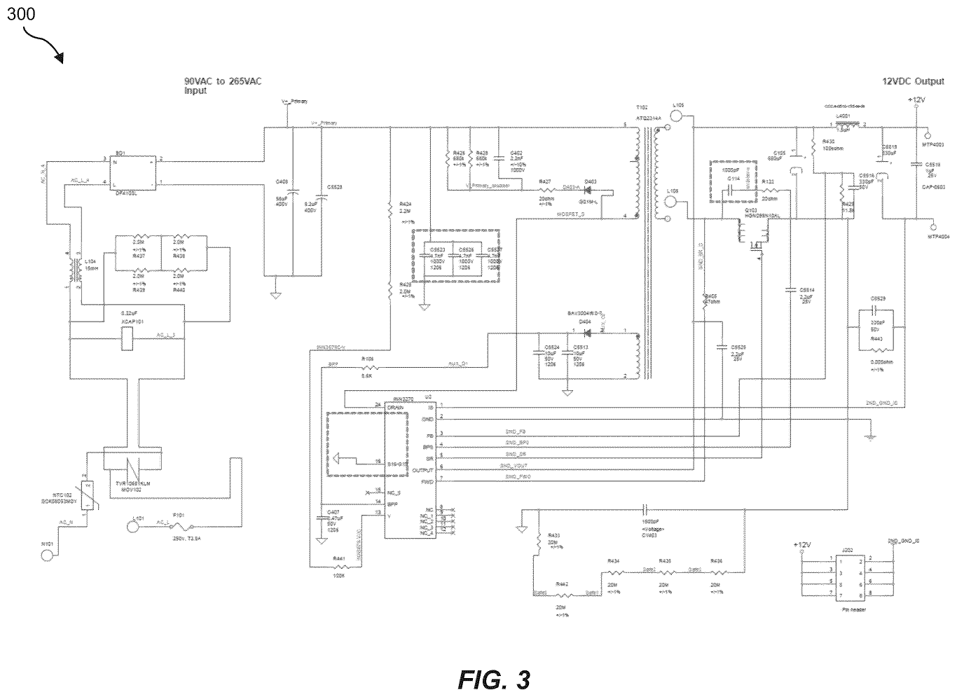

FIG. 3 is a schematic circuit diagram of a power supply board 300 for a wireless communications device, according to at least one embodiment of the present disclosure. The power supply board 300 schematically described FIG. 3 may be the same as or similar to the power supply board 100 of FIG. 1. For example, an NTC 304 may be the same as or similar to the NTC 104 of FIG. 1. An MOV 306 may be the same as or similar to the MOV 106 of FIG. 1. An input ECAP 308 may be the same as or similar to the input ECAP 108 of FIG. 1. An output ECAP 310 may be the same as or similar to the output ECAP 110 of FIG. 1. An XCAP 312 may be the same as or similar to the XCAP 112 of FIG. 1. A transformer 316 may be the same as or similar to the transformer 116 of FIG. 1.

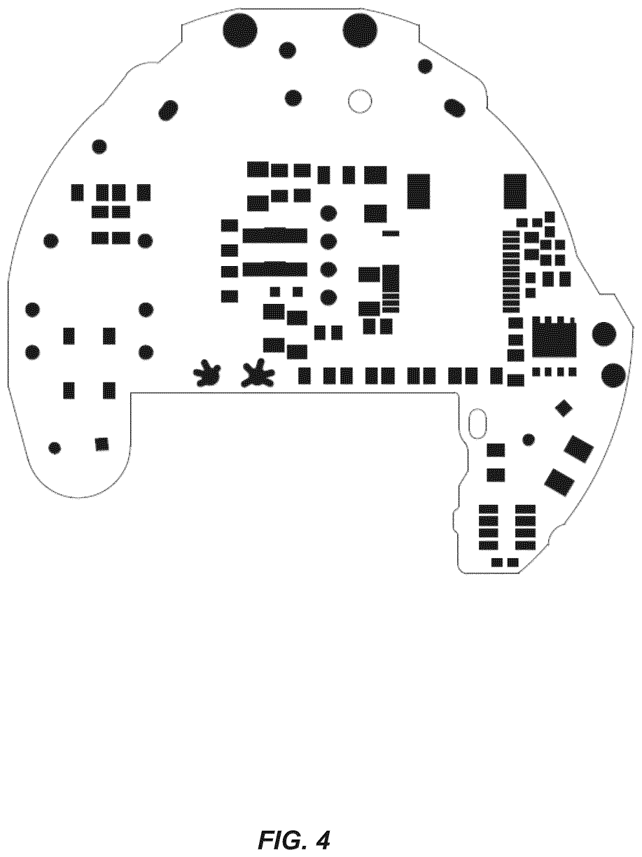

FIGS. 4-14 illustrate a printed circuit layout of respective layers 400A-400K of a power supply board for a wireless communications device, according to at least one embodiment of the present disclosure. The presence, location, shape, and configuration of the different components and elements of the printed circuit layout may provide functionality to the power supply board. In addition, these aspects of the printed circuit layout may improve an efficiency and performance of the power supply board, while conforming to a design margin. In some examples, the printed circuit layout as shown in FIGS. 4-14 may be further modified, such as to accommodate additional or different functional components, to remove one or more components, to move a component from one location on the power supply board to another location, etc. In additional examples, an outline of the power supply board may be altered, such as corresponding to adjacent elements of a system using the power supply board, such as a wireless communications device.

For example, FIG. 4 illustrates a printed circuit layout for a first layer 400A of the power supply board. The first layer 400A may include a first PCB substrate 402A, which may include first through holes 420A and first conductors 422A (shown as shaded) printed or otherwise deposited on the first PCB substrate 402A in the arrangement illustrated in FIG. 4. The first conductors 422A may be in the form of conductive pads, traces, vias, etc.

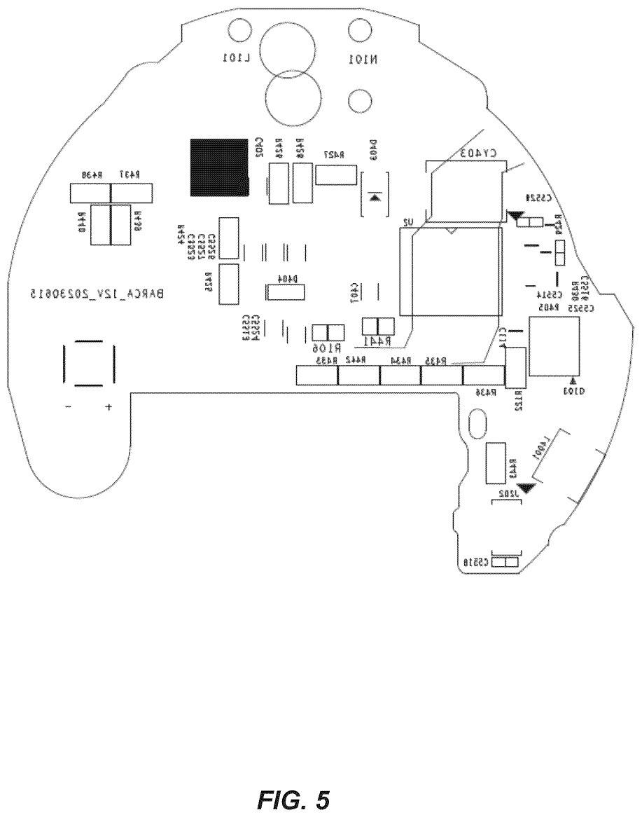

FIG. 5 illustrates a printed circuit layout for a second layer 400B of the power supply board. The second layer 400B may include a second PCB substrate 402B, which may include second through holes 420B and one or more second conductors 422B (shown as shaded) printed or otherwise deposited on the second PCB substrate 402B in the arrangement illustrated in FIG. 5. The second conductors 422B may be in the form of conductive pads, traces, vias, etc. FIG. 5 also illustrates indicators 424B for mounting various components on the power supply board, such as on a back side of the power supply board 100 shown in FIG. 1, for example. In some embodiments, one or more of the indicators 424B may be printed on the second PCB substrate 402B, such as via a silk-screening process.

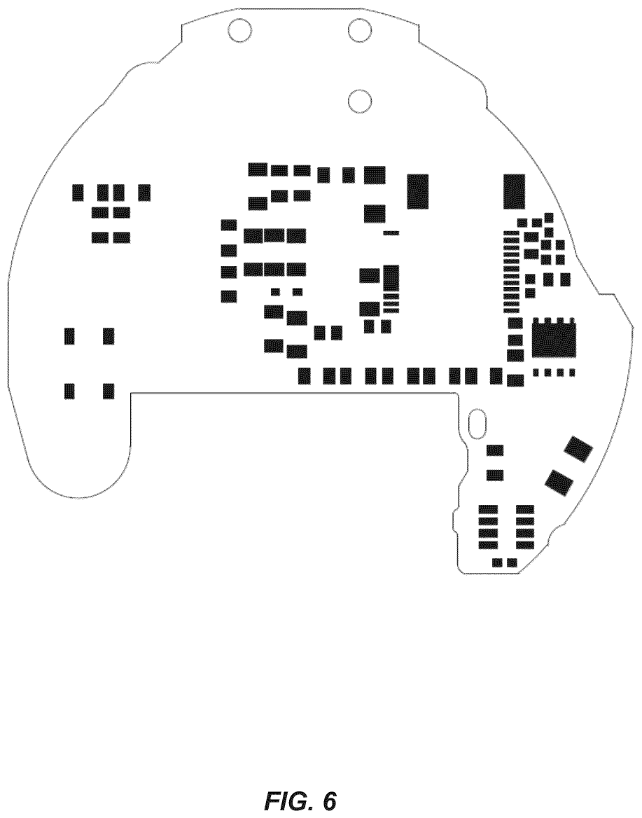

FIG. 6 illustrates a printed circuit layout for a third layer 400C of the power supply board. The third layer 400C may include a third PCB substrate 402C, which may include third through holes 420C and third conductors 422C (shown as shaded) printed or otherwise deposited on the third PCB substrate 402C in the arrangement illustrated in FIG. 6. The third conductors 422C may be in the form of conductive pads, traces, vias, etc.

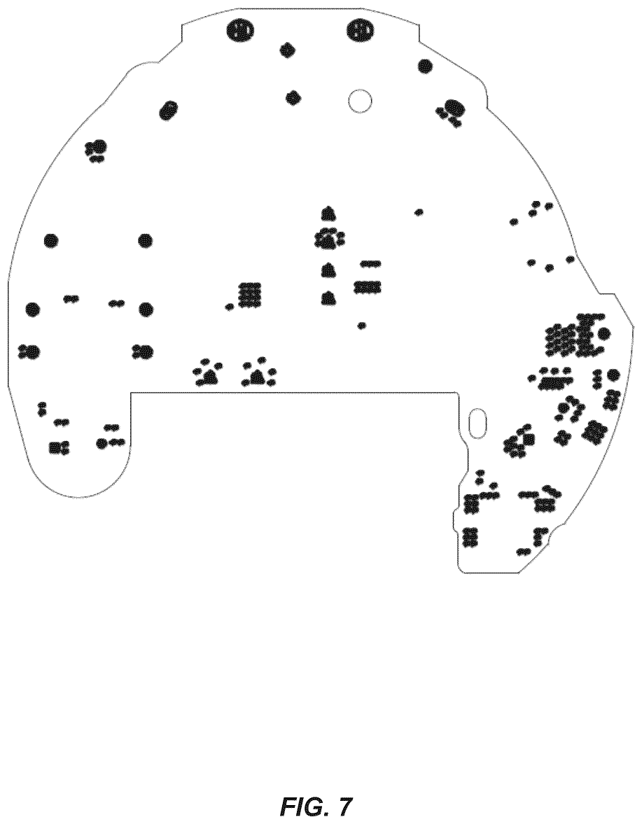

FIG. 7 illustrates a layout plan 400D for plated holes 426D (e.g., vias) in the fourth PCB substrate 402D. In some examples, the plated holes 426D may be formed by drilling through the fourth PCB substrate 402D and depositing a conductive material on internal surfaces of the plated holes 426D. Holes 420D that are not plated may also be present, as illustrated in FIG. 7.

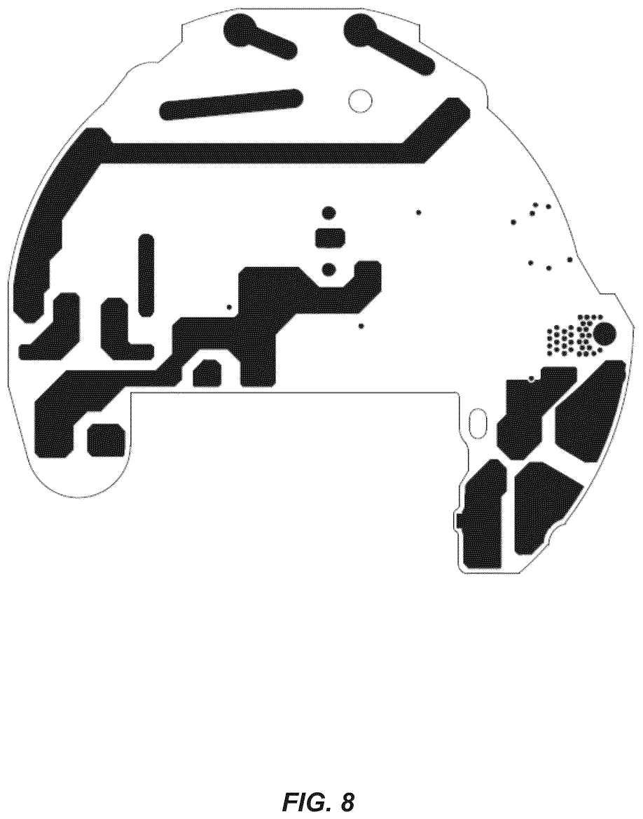

FIG. 8 illustrates a printed circuit layout for a fifth layer 400E of the power supply board. The fifth layer 400E may include a fifth PCB substrate 402E, which may include fifth through holes 420E and fifth conductors 422E (shown as shaded) printed or otherwise deposited on the fifth PCB substrate 402E in the arrangement illustrated in FIG. 8. The fifth conductors 422E may be in the form of conductive pads, traces, vias, etc.

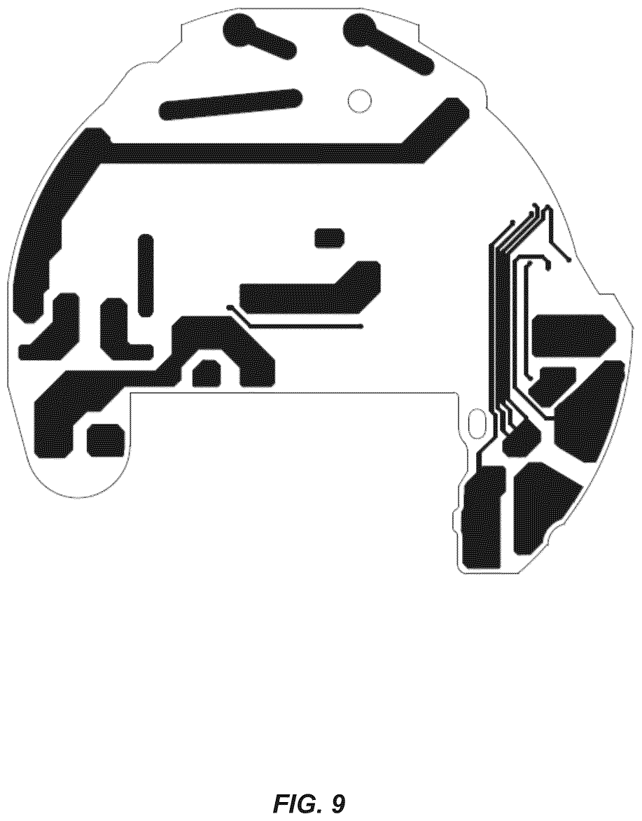

FIG. 9 illustrates a printed circuit layout for a sixth layer 400F of the power supply board. The sixth layer 400F may include a sixth PCB substrate 402F, which may include sixth through holes 420F and sixth conductors 422F (shown as shaded) printed or otherwise deposited on the sixth PCB substrate 402F in the arrangement illustrated in FIG. 9. The sixth conductors 422F may be in the form of conductive pads, traces, vias, etc.

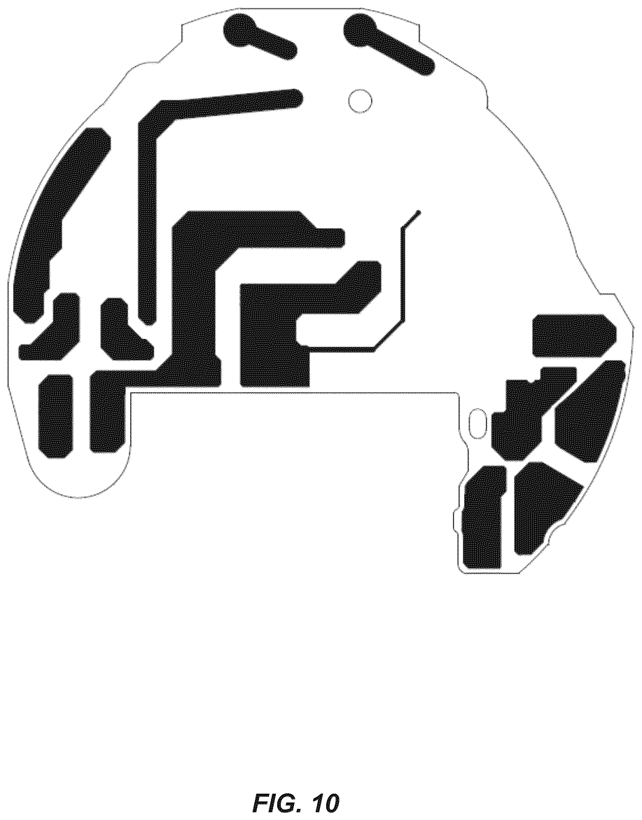

FIG. 10 illustrates a printed circuit layout for a seventh layer 400G of the power supply board. The seventh layer 400G may include a seventh PCB substrate 402G, which may include seventh through holes 420G and seventh conductors 422G (shown as shaded) printed or otherwise deposited on the seventh PCB substrate 402G in the arrangement illustrated in FIG. 10. The seventh conductors 422G may be in the form of conductive pads, traces, vias, etc.

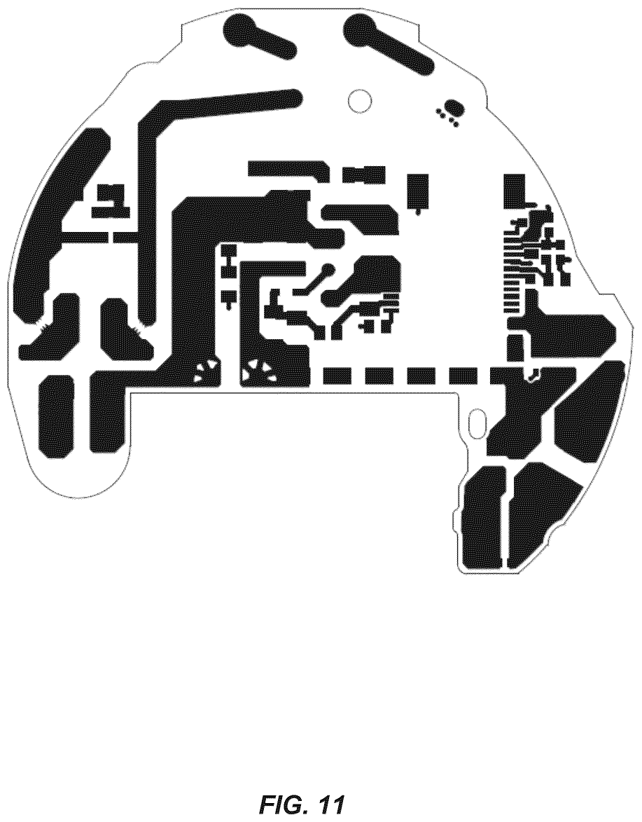

FIG. 11 illustrates a printed circuit layout for an eighth layer 400H of the power supply board. The eighth layer 400H may include an eighth PCB substrate 402H, which may include eighth through holes 420H and eighth conductors 422H (shown as shaded) printed or otherwise deposited on the eighth PCB substrate 402H in the arrangement illustrated in FIG. 11. The eighth conductors 422H may be in the form of conductive pads, traces, vias, etc.

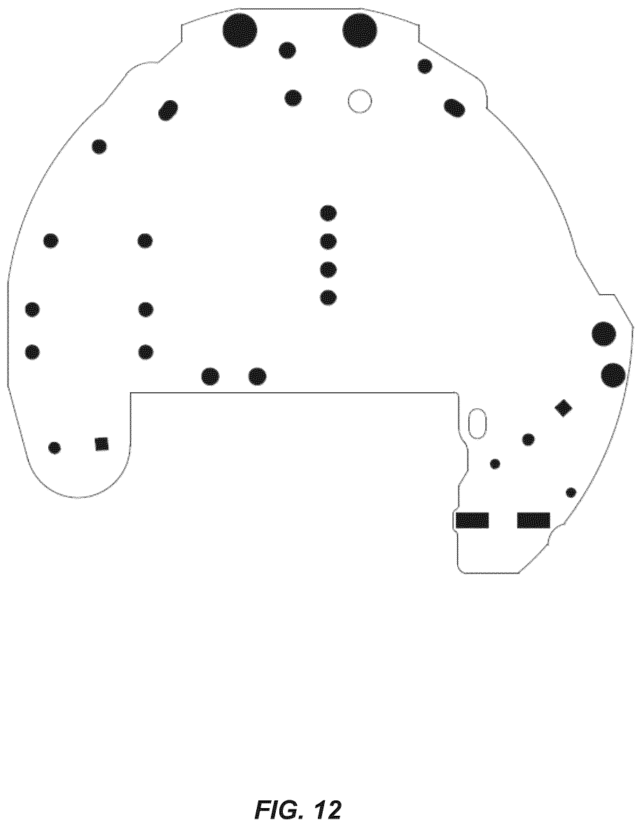

FIG. 12 illustrates a printed circuit layout for a ninth layer 400I of the power supply board. The ninth layer 400I may include a ninth PCB substrate 402I, which may include ninth through holes 420I and ninth conductors 422I (shown as shaded) printed or otherwise deposited on the ninth PCB substrate 402I in the arrangement illustrated in FIG. 12. The ninth conductors 422I may be in the form of conductive pads, traces, vias, etc.

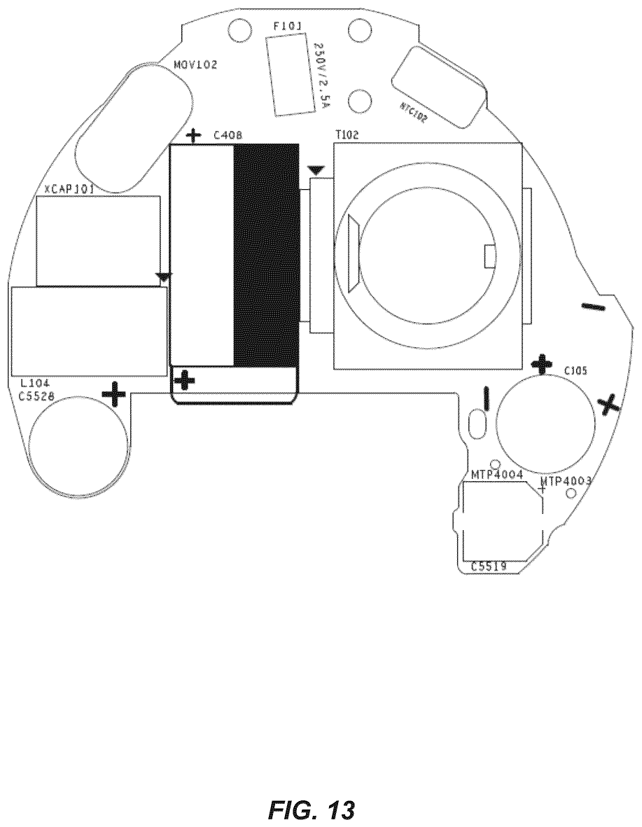

FIG. 13 illustrates a printed circuit layout for a tenth layer 400J of the power supply board. The tenth layer 400J may include a tenth PCB substrate 402J, which may include tenth through holes 420J and one or more tenth conductors 422J (shown as shaded) printed or otherwise deposited on the tenth PCB substrate 402J in the arrangement illustrated in FIG. 13. The tenth conductors 422J may be in the form of conductive pads, traces, vias, etc. FIG. 13 also illustrates indicators 424J for mounting various components on the power supply board, such as on a front side of the power supply board 100 shown in FIG. 1, for example. In some embodiments, one or more of the indicators 424J may be printed on the tenth PCB substrate 402J, such as via a silk-screening process.

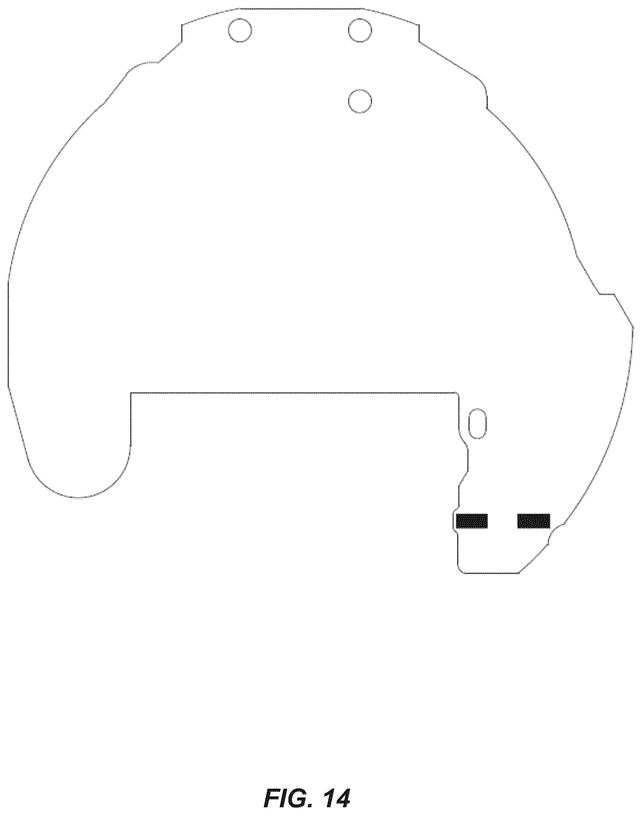

FIG. 14 illustrates a printed circuit layout for an eleventh layer 400K of the power supply board. The eleventh layer 400K may include an eleventh PCB substrate 402K, which may include eleventh through holes 420K and eleventh conductors 422K (shown as shaded) printed or otherwise deposited on the eleventh PCB substrate 402K in the arrangement illustrated in FIG. 14. The eleventh conductors 422K may be in the form of conductive pads, traces, vias, etc.

The conductors 422A-422K and plated holes 426D may form connections (e.g., as shown in FIG. 3) between various components of the power supply board.

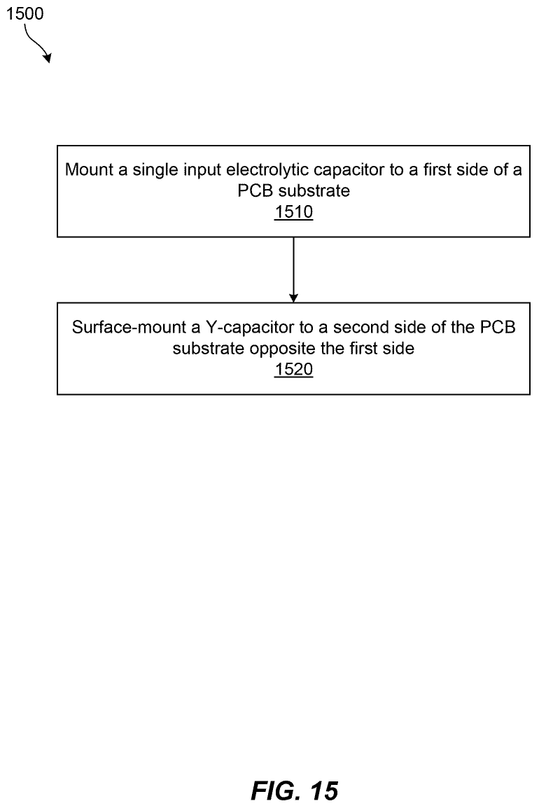

FIG. 15 is a flow diagram illustrating a method 1500 of forming a power supply board, according to at least one embodiment of the present disclosure.

At operation 1510, a single input electrolytic capacitor may be mounted to a first side of a PCB substrate. The single input electrolytic capacitor may be operably coupled to power supply circuitry of the PCB substrate.

At operation 1520, a Y-capacitor may be surface-mounted to a second side of the PCB substrate opposite the first side. The Y-capacitor may be operably coupled to the power supply circuitry of the PCB substrate.

In some examples, mounting the input electrolytic capacitor to the first side of the PCB substrate may include mounting the input electrolytic capacitor to the PCB substrate in a 90-degree bent configuration such that a body of the input electrolytic capacitor lies along the first side of the PCB substrate.

Accordingly, the present disclosure includes power supply boards that may be compact while still being functional, including with acceptable creepage and clearance for the components and/or conductive elements thereof. In some embodiments, power supply boards of the present disclosure may include a single input electrolytic capacitor mounted to a PCB substrate (e.g., in a 90-degree bent configuration) and/or a Y-capacitor surface-mounted to the PCB substrate (e.g., on an opposing side of the PCB substrate from the input electrolytic capacitor). In additional embodiments, power supply boards of the present disclosure may include a transformer that includes a bobbin and a core (e.g., a ferrite core). The bobbin may include a lower flange, lower pins extending downward from the lower flange, a central cylinder extending upward from the lower flange, and an upper flange on an opposing side of the central cylinder from the lower flange. The core may include a peripheral recess, and the lower pins of the bobbin may pass through the peripheral recess.

The following example embodiments are also included in the present disclosure:

Example 1. A power supply board for a wireless communication device, the power supply board including: a printed circuit board (PCB) substrate including power supply circuitry; a single input electrolytic capacitor mounted to the PCB substrate and operably coupled to the power supply circuitry; and a Y-capacitor surface-mounted to the PCB substrate on an opposing side of the PCB substrate from the input electrolytic capacitor, wherein the Y-capacitor is operably coupled to the power supply circuitry.

Example 2. The power supply board of Example 1, wherein the input electrolytic capacitor is mounted to the PCB substrate in a bent configuration such that a body of the input electrolytic capacitor lies along a surface of the PCB substrate.

Example 3. The power supply board of Example 2, wherein the input electrolytic capacitor is mounted to the PCB substrate in a 90-degree bent configuration.

Example 4. The power supply board of any one of Examples 1 through 3, further including a negative temperature coefficient thermistor mounted to the PCB substrate and operably coupled to the power supply circuitry.

Example 5. The power supply board of any one of Examples 1 through 4, further including a metal oxide varistor mounted to the PCB substrate and operably coupled to the power supply circuitry.

Example 6. The power supply board of any one of Examples 1 through 5, further including an output electrolytic capacitor mounted to the PCB substrate and operably coupled to the power supply circuitry.

Example 7. The power supply board of any one of Examples 1 through 6, further including an X-capacitor mounted to the PCB substrate and operably coupled to the power supply circuitry.

Example 8. The power supply board of any one of Examples 1 through 7, further including a common-mode choke mounted to the PCB substrate and operably coupled to the power supply circuitry.

Example 9. The power supply board of any one of Examples 1 through 8, further including a transformer mounted to the PCB substrate and operably coupled to the power supply circuitry.

Example 10. The power supply board of Example 9, wherein the transformer includes: a bobbin including a lower flange, lower pins extending downward from the lower flange, a central cylinder extending upward from the lower flange, an upper flange on an opposing side of the central cylinder from the lower flange, and upper pins extending from the upper flange; and a ferrite core coupled to the bobbin, the ferrite core including a peripheral recess, wherein the lower pins of the bobbin pass through the peripheral recess.

Example 11. The power supply board of Example 10, wherein the bobbin has a maximum bobbin width and the ferrite core has an internal core width from an inner edge of the peripheral recess to an opposing side of the ferrite core, wherein a ratio of the maximum bobbin width to the internal core width is less than 150%.

Example 12. The power supply board of Example 11, wherein the ratio is about 130% or less.

Example 13. The power supply board of any one of Examples 1 through 12, further including a fuse mounted to the PCB substrate and operably coupled to the power supply circuitry.

Example 14. The power supply board of any one of Examples 1 through 13, further including: a negative temperature coefficient thermistor mounted to a same side of the PCB substrate as the input electrolytic capacitor, wherein the negative temperature coefficient thermistor is operably coupled to the power supply circuitry; a metal oxide varistor mounted to the same side of the PCB substrate as the input electrolytic capacitor, wherein the metal oxide varistor is operably coupled to the power supply circuitry; an output electrolytic capacitor mounted to the same side of the PCB substrate as the input electrolytic capacitor, wherein the output electrolytic capacitor is operably coupled to the power supply circuitry; an X-capacitor mounted to the same side of the PCB substrate as the input electrolytic capacitor, wherein the X-capacitor is operably coupled to the power supply circuitry; a common-mode choke mounted to the same side of the PCB substrate as the input electrolytic capacitor, wherein the common-mode choke is operably coupled to the power supply circuitry; a transformer mounted to the same side of the PCB substrate as the input electrolytic capacitor, wherein the transformer is operably coupled to the power supply circuitry; and a fuse mounted to the same side of the PCB substrate as the input electrolytic capacitor, wherein the fuse is operably coupled to the power supply circuitry.

Example 15. A power supply board for a wireless communication device, the power supply board including: a printed circuit board (PCB) substrate including power supply circuitry; a single input electrolytic capacitor mounted to a first side of the PCB substrate in a 90-degree bent configuration and operably coupled to the power supply circuitry; a Y-capacitor mounted to a second side of the PCB substrate opposite the first side, wherein the Y-capacitor is operably coupled to the power supply circuitry; and a transformer mounted to the PCB substrate on the first side of the PCB substrate and operably coupled to the power supply circuitry, the transformer including: a bobbin including a lower flange, lower pins extending downward from the lower flange, a central cylinder extending upward from the lower flange, and an upper flange on an opposing side of the central cylinder from the lower flange; and a ferrite core coupled to the bobbin, the ferrite core including a peripheral recess, wherein the lower pins of the bobbin pass through the peripheral recess.

Example 16. The power supply board of Example 15, wherein the bobbin of the transformer further includes upper pins extending from the upper flange.

Example 17. The power supply board of Example 15 or Example 16, wherein the bobbin has a maximum bobbin width and the ferrite core has an internal core width from an inner edge of the peripheral recess to an opposing side of the ferrite core, wherein a ratio of the maximum bobbin width to the internal core width is less than 150%.

Example 18. The power supply board of any one of Examples 15 through 17, wherein the Y-capacitor is surface-mounted to the second side of the PCB substrate.

Example 19. A method of forming a power supply board, the method including: mounting a single input electrolytic capacitor to a first side of a PCB substrate and operably coupling the input electrolytic capacitor to power supply circuitry of the PCB substrate; and surface-mounting a Y-capacitor to a second side of the PCB substrate opposite the first side and operably coupling the Y-capacitor to the power supply circuitry of the PCB substrate.

Example 20. The method of Example 19, wherein mounting the input electrolytic capacitor to the first side of the PCB substrate includes mounting the input electrolytic capacitor to the PCB substrate in a 90-degree bent configuration such that a body of the input electrolytic capacitor lies along the first side of the PCB substrate.

The preceding description has been provided to enable others skilled in the art to best utilize various aspects of the example embodiments disclosed herein. This example description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to any claims appended hereto and their equivalents in determining the scope of the present disclosure.

Unless otherwise noted, the terms “connected to” and “coupled to” (and their derivatives), as used in the specification and/or claims, are to be construed as permitting both direct and indirect (i.e., via other elements or components) connection. In addition, the terms “a” or “an,” as used in the specification and/or claims, are to be construed as meaning “at least one of.” Finally, for ease of use, the terms “including” and “having” (and their derivatives), as used in the specification and/or claims, are interchangeable with and have the same meaning as the word “comprising.”

What is claimed is:

1. A power supply board for a wireless communication device, the power supply board comprising:
a printed circuit board (PCB) substrate comprising power supply circuitry;
a single input electrolytic capacitor mounted to the PCB substrate and operably coupled to the power supply circuitry; and
a Y-capacitor surface-mounted to the PCB substrate on an opposing side of the PCB substrate from the input electrolytic capacitor, wherein the Y-capacitor is operably coupled to the power supply circuitry.

2. The power supply board of claim 1, wherein the input electrolytic capacitor is mounted to the PCB substrate in a bent configuration such that a body of the input electrolytic capacitor lies along a surface of the PCB substrate.

3. The power supply board of claim 2, wherein the input electrolytic capacitor is mounted to the PCB substrate in a 90-degree bent configuration.

4. The power supply board of claim 1, further comprising a negative temperature coefficient thermistor mounted to the PCB substrate and operably coupled to the power supply circuitry.

5. The power supply board of claim 1, further comprising a metal oxide varistor mounted to the PCB substrate and operably coupled to the power supply circuitry.

6. The power supply board of claim 1, further comprising an output electrolytic capacitor mounted to the PCB substrate and operably coupled to the power supply circuitry.

7. The power supply board of claim 1, further comprising an X-capacitor mounted to the PCB substrate and operably coupled to the power supply circuitry.

8. The power supply board of claim 1, further comprising a common-mode choke mounted to the PCB substrate and operably coupled to the power supply circuitry.

9. The power supply board of claim 1, further comprising a transformer mounted to the PCB substrate and operably coupled to the power supply circuitry.

10. The power supply board of claim 9, wherein the transformer comprises:
a bobbin including a lower flange, lower pins extending downward from the lower flange, a central cylinder extending upward from the lower flange, an upper flange on an opposing side of the central cylinder from the lower flange, and upper pins extending from the upper flange; and
a ferrite core coupled to the bobbin, the ferrite core including a peripheral recess, wherein the lower pins of the bobbin pass through the peripheral recess.

11. The power supply board of claim 10, wherein the bobbin has a maximum bobbin width and the ferrite core has an internal core width from an inner edge of the peripheral recess to an opposing side of the ferrite core, wherein a ratio of the maximum bobbin width to the internal core width is less than 150%.

12. The power supply board of claim 11, wherein the ratio is about 130% or less.

13. The power supply board of claim 1, further comprising a fuse mounted to the PCB substrate and operably coupled to the power supply circuitry.

14. The power supply board of claim 1, further comprising:
a negative temperature coefficient thermistor mounted to a same side of the PCB substrate as the input electrolytic capacitor, wherein the negative temperature coefficient thermistor is operably coupled to the power supply circuitry;
a metal oxide varistor mounted to the same side of the PCB substrate as the input electrolytic capacitor, wherein the metal oxide varistor is operably coupled to the power supply circuitry;
an output electrolytic capacitor mounted to the same side of the PCB substrate as the input electrolytic capacitor, wherein the output electrolytic capacitor is operably coupled to the power supply circuitry;
an X-capacitor mounted to the same side of the PCB substrate as the input electrolytic capacitor, wherein the X-capacitor is operably coupled to the power supply circuitry;
a common-mode choke mounted to the same side of the PCB substrate as the input electrolytic capacitor, wherein the common-mode choke is operably coupled to the power supply circuitry;
a transformer mounted to the same side of the PCB substrate as the input electrolytic capacitor, wherein the transformer is operably coupled to the power supply circuitry; and
a fuse mounted to the same side of the PCB substrate as the input electrolytic capacitor, wherein the fuse is operably coupled to the power supply circuitry.

15. A power supply board for a wireless communication device, the power supply board comprising:
a printed circuit board (PCB) substrate comprising power supply circuitry;
a single input electrolytic capacitor mounted to a first side of the PCB substrate in a 90-degree bent configuration and operably coupled to the power supply circuitry;
a Y-capacitor mounted to a second side of the PCB substrate opposite the first side, wherein the Y-capacitor is operably coupled to the power supply circuitry; and
a transformer mounted to the PCB substrate on the first side of the PCB substrate and operably coupled to the power supply circuitry, the transformer comprising:
a bobbin including a lower flange, lower pins extending downward from the lower flange, a central cylinder extending upward from the lower flange, and an upper flange on an opposing side of the central cylinder from the lower flange; and
a ferrite core coupled to the bobbin, the ferrite core including a peripheral recess, wherein the lower pins of the bobbin pass through the peripheral recess.

16. The power supply board of claim 15, wherein the bobbin of the transformer further comprises upper pins extending from the upper flange.

17. The power supply board of claim 15, wherein the bobbin has a maximum bobbin width and the ferrite core has an internal core width from an inner edge of the peripheral recess to an opposing side of the ferrite core, wherein a ratio of the maximum bobbin width to the internal core width is less than 150%.

18. The power supply board of claim 15, wherein the Y-capacitor is surface-mounted to the second side of the PCB substrate.

19. A method of forming a power supply board, the method comprising:
mounting a single input electrolytic capacitor to a first side of a PCB substrate and operably coupling the input electrolytic capacitor to power supply circuitry of the PCB substrate; and
surface-mounting a Y-capacitor to a second side of the PCB substrate opposite the first side and operably coupling the Y-capacitor to the power supply circuitry of the PCB substrate.

20. The method of claim 19, wherein mounting the input electrolytic capacitor to the first side of the PCB substrate comprises mounting the input electrolytic capacitor to the PCB substrate in a 90-degree bent configuration such that a body of the input electrolytic capacitor lies along the first side of the PCB substrate.
